(19) United States
(12) Patent Application Publication
(10) Pub. No.: US 2026/0006885 A1
(43) Pub. Date: Jan. 1, 2026

(54) DIELECTRIC ELEMENT AND APPLICATION OF THE SAME

(71) Applicant: National Tsing Hua University, Hsinchu City (TW)

(72) Inventors: Yung-Chun WU, Hsinchu City (TW); Fu-Ju HOU, Hsinchu City (TW); Yi-Ju YAO, New Taipei City (TW)

(73) Assignee: National Tsing Hua University, Hsinchu City (TW)

(21) Appl. No.: 18/935,794

(22) Filed: Nov. 4, 2024

(30) Foreign Application Priority Data
Jun. 26, 2024 (TW) 113123830

(51) Int. Cl. H01L 29/51; H01L 29/06; H01L 29/423

(52) U.S. Cl. CPC H10D 64/685; H10D 1/043; H10D 1/714; H10D 30/6735; H10D 62/102; H10D 64/514; H10D 64/691

(57) ABSTRACT

A dielectric element includes a superlattice structure which includes hafnium dioxide (HfO₂) layers and zirconium dioxide (ZrO₂) layers that are alternately stacked. The superlattice structure has a total thickness ranging from 2.0 nm to 5.5 nm and has a dielectric constant (K) ranging from 30 to 53. A thickness ratio of the hafnium dioxide layers to the zirconium dioxide layers is 1:1. A field-effect transistor (FET), a logic integrated circuit (logic IC), and a metal-insulator-metal (MIM) capacitor are also provided.

### CROSS-REFERENCE TO RELATED APPLICATION

This application claims priority to Taiwanese Invention patent application No. 113123830, filed on Jun. 26, 2024, the entire disclosure of which is incorporated by reference herein.

### FIELD

The present disclosure relates to a dielectric element and application of the same.

### BACKGROUND

Logic integrated circuits (logic ICs) are semiconductor devices each containing a large number of transistors. The most commonly used transistors in the logic ICs are field-effect transistors (FETs), in which the most widely used types are gate-all-around field-effect transistors (GAAFETs) and fin field-effect transistor (FinFETs). In a FinFET, the channel has a vertical structure. In a GAAFET, the channel has a horizontal structure, which provides a relatively large contact area between the gate and the channel.

A conventional FET usually suffers from gate leakage current problems, which may reduce transmission efficiency thereof, leading to low computational performance and increased power consumption in a logic IC. In addition, as the size of the conventional FET continues to shrink, effective reduction in the gate leakage current problems of the conventional FET becomes increasingly challenging.

In view of the aforesaid, there is still a need to develop a dielectric element (e.g., a superlattice structure), which has a relatively high dielectric constant (K) and a relatively low equivalent oxide thickness (EOT), and which is suitable for use in a FET, a logic IC, and a metal-insulator-metal (MIM) capacitor.

### SUMMARY

Therefore, in a first aspect, the present disclosure provides a dielectric element, which can alleviate at least one of the drawbacks of the prior art. The dielectric element includes a superlattice structure which includes hafnium dioxide (HfO₂) layers and zirconium dioxide (ZrO₂) layers that are alternately stacked. The superlattice structure has a total thickness ranging from 2.0 nm to 5.5 nm and has a dielectric constant (K) ranging from 30 to 53. A thickness ratio of the hafnium dioxide layers to the zirconium dioxide layers is 1:1.

In a second aspect, the present disclosure provides a field-effect transistor (FET), which can alleviate at least one of the drawbacks of the prior art. The FET includes a channel region, the aforesaid dielectric element serving as a gate dielectric layer and formed over the channel region, and a metal gate formed over the gate dielectric layer.

In a third aspect, the present disclosure provides a logic integrated circuit (logic IC), which can alleviate at least one of the drawbacks of the prior art. The logic IC includes the aforesaid FET.

In a fourth aspect, the present disclosure provides a metal-insulator-metal (MIM) capacitor, which can alleviate at least one of the drawbacks of the prior art. The MIM capacitor includes the aforesaid dielectric element.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a superlattice structure included in a dielectric element according to the present disclosure, in which the symbol “ . . . ” represents hafnium oxide layers and zirconium oxide layers that are repeatedly staggered and stacked in the superlattice structure.

FIG. 2 is a schematic view illustrating a metal-insulator-metal (MIM) capacitor according to the present disclosure, in which the symbol “ . . . ” represents the hafnium oxide layers and the zirconium oxide layers that are repeatedly staggered and stacked in the superlattice structure.

FIGS. 3 to 5 are graphs illustrating current density-voltage (J-V) curves of the MIM capacitors of Examples 1 to 10 (EX1 to EX10).

FIG. 6 is a graph illustrating a polarization-voltage (P-V) hysteresis loop of the MIM capacitor of EX1.

FIG. 7 is a partially schematic view of a gate-all-around field-effect transistor (GAAFET) according to the present disclosure.

FIG. 8 is a graph illustrating drain current-gate voltage (I_{D}-V_{G}) curves of the GAAFETs of Example 1′ (EX1′) and Comparative Example 1′ (CE1′).

FIG. 9 is a graph illustrating drain current-drain voltage (I_{D}-V_{D}) curves of the GAAFETs of EX1′ and CE1′.

### DETAILED DESCRIPTION

For the purpose of this specification, it will be clearly understood that the word “comprising” means “including but not limited to”, and that the word “comprises” has a corresponding meaning.

It is to be understood that, if any prior art publication is referred to herein, such reference does not constitute an admission that the publication forms a part of the common general knowledge in the art, in Taiwan or any other country.

Unless otherwise defined, all technical and scientific terms used herein have the meaning commonly understood by a person skilled in the art to which the present disclosure belongs. One skilled in the art will recognize many methods and materials similar or equivalent to those described herein, which could be used in the practice of the present disclosure. Indeed, the present disclosure is in no way limited to the methods and materials described.

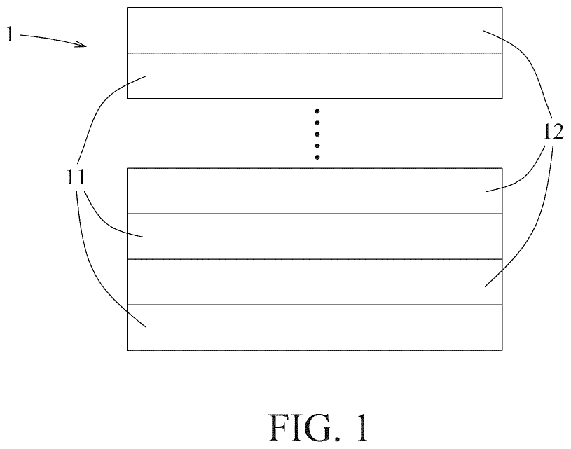

Referring to FIG. 1, a dielectric element according to the present disclosure includes a superlattice structure 1 which includes hafnium dioxide (HfO₂) layers 11 and zirconium dioxide (ZrO₂) layers 12 that are alternately stacked. The superlattice structure 1 has a total thickness ranging from 2.0 nm to 5.5 nm and has a dielectric constant (K) ranging from 30 to 53. A thickness ratio of the hafnium dioxide layers 11 to the zirconium dioxide layers 12 is 1:1. In certain embodiments, the superlattice structure 1 has a total thickness ranging from 4.7 nm to 4.9 nm. In certain embodiments, the superlattice structure 1 has a dielectric constant (K) ranging from 32 to 53.

According to the present disclosure, the total number of the hafnium dioxide layers 11 is equal to the total number of the zirconium dioxide layers 12. In certain embodiments, the number of the hafnium dioxide layers 11 and the number of the zirconium dioxide layers 12 are each either 2, 3, or 5 layers.

According to the present disclosure, each of the hafnium dioxide layers 11 has a thickness ranging from 0.3 nm to 1.5 nm, and each of the zirconium dioxide layers 12 has a thickness ranging from 0.3 nm to 1.5 nm. In certain embodiments, each of the hafnium dioxide layers 11 has a thickness of 0.5 nm, 0.8 nm, or 1.3 nm, and each of the zirconium dioxide layers 12 has a thickness of 0.5 nm, 0.8 nm, or 1.3 nm.

According to the present disclosure, the superlattice structure 1 is prepared by subjecting the hafnium dioxide layers 11 and the zirconium dioxide layers 12 to a rapid thermal annealing (RTA) process at a temperature ranging from 450° C. to 800° C. The dielectric constant (K) of the superlattice structure 1 is controlled by both the thickness thereof and the temperature of the RTA process. In certain embodiments, the superlattice structure 1 is prepared by subjecting the hafnium dioxide layers 11 each having a thickness of 0.5 nm and the zirconium dioxide layers 12 each having a thickness of 0.5 nm to a RTA process at a temperature ranging from 450° C. to 750° C. In certain embodiments, the superlattice structure 1 is prepared by subjecting the hafnium dioxide layers 11 each having a thickness of 0.8 nm and the zirconium dioxide layers 12 each having a thickness of 0.8 nm to a RTA process at a temperature ranging from 450° C. to 650° C. In certain embodiments, the superlattice structure 1 is prepared by subjecting the hafnium dioxide layers 11 each having a thickness of 1.3 nm and the zirconium dioxide layers 12 each having a thickness of 1.3 nm to a RTA process at a temperature ranging from 450° C. to 650° C.

In certain embodiments, an exemplary method for preparing each of the hafnium dioxide layers 11 includes the following steps in sequence: depositing a hafnium precursor by an atomic layer deposition (ALD) process so as to form a hafnium layer; introducing argon gas to remove the thus excess hafnium precursor from the hafnium layer; and introducing an oxygen plasma to react with the hafnium layer so as to form each of the hafnium dioxide layers 11. An example of the hafnium precursor may include, but is not limited to, tetrakis(ethylmethylamino) hafnium (TEMAH). In certain embodiments, the argon gas may be introduced at a flow rate of 20 sccm, and the oxygen plasma may be introduced at a wattage of 300 W and a flow rate of 20 sccm.

In certain embodiments, an exemplary method for preparing each of the zirconium dioxide layers 12 includes the following steps in sequence: depositing a zirconium precursor by an ALD process so as to form a zirconium layer; introducing argon gas to remove the thus excess zirconium precursor from the zirconium layer; and introducing an oxygen plasma to react with the zirconium layer so as to form each of the zirconium dioxide layers 12. An example of zirconium precursor may include, but is not limited to, tetrakis(ethylmethylamino) zirconium (TEMAZ). In certain embodiments, the argon gas may be introduced at a flow rate of 20 sccm, and the oxygen plasma may be introduced at a wattage of 300 W and a flow rate of 20 sccm.

The present disclosure also provides a metal-insulator-metal (MIM) capacitor 8 which includes the aforesaid superlattice structure 1.

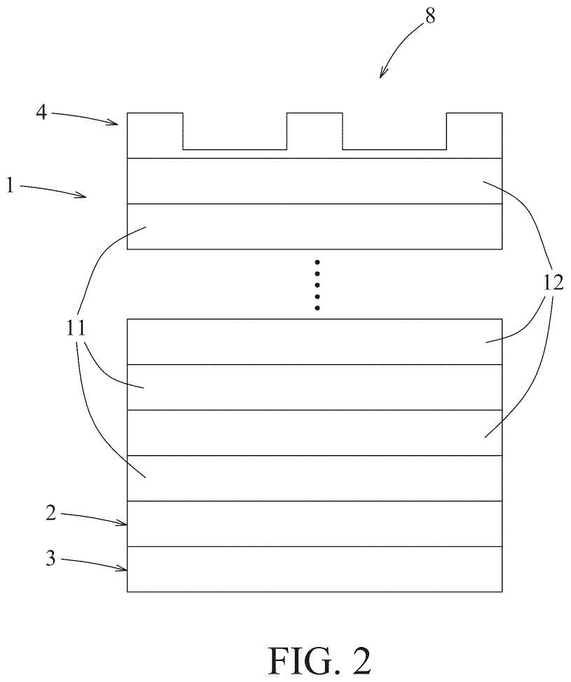

Referring to FIG. 2, the MIM capacitor 8 includes the superlattice structure 1, a lower electrode layer 2 disposed on a surface of the superlattice structure 1, a silicon substrate 3 disposed on a surface of the lower electrode layer 2 opposite to the superlattice structure 1, and an upper electrode layer 4 disposed on another surface of the superlattice structure 1 opposite to the lower electrode layer 2. To be specific, the superlattice structure 1 includes the hafnium dioxide layers 11 and the zirconium dioxide layers 12 that are alternately stacked in equal numbers, in which one of the hafnium dioxide layers 11 is in contact with another surface of the lower electrode layer 2 opposite to the silicon substrate 3, while one of the zirconium dioxide layers 12 is in contact with a surface of the upper electrode layer 4.

It should be noted that the materials and types of the lower electrode layer 2, the silicon substrate 3, and the upper electrode layer 4 are not particularly limited, and may be flexibly adjusted and selected by a person skilled in the art according to practical requirements. For example, the silicon substrate 3 made of silicon is subjected to a Radio Corporation of America (RCA) standard cleaning process. An example of the material for a respective one of the lower electrode layer 2 and the upper electrode layer 4 may include, but is not limited to, titanium nitride (TiN). In certain embodiments, the lower electrode layer 2 may have a thickness of 80 nm, and the upper electrode layer 4 may have a maximum thickness of 80 nm.

According to the present disclosure, the MIM capacitor 8 may be prepared using techniques well-known to those skilled in the art.

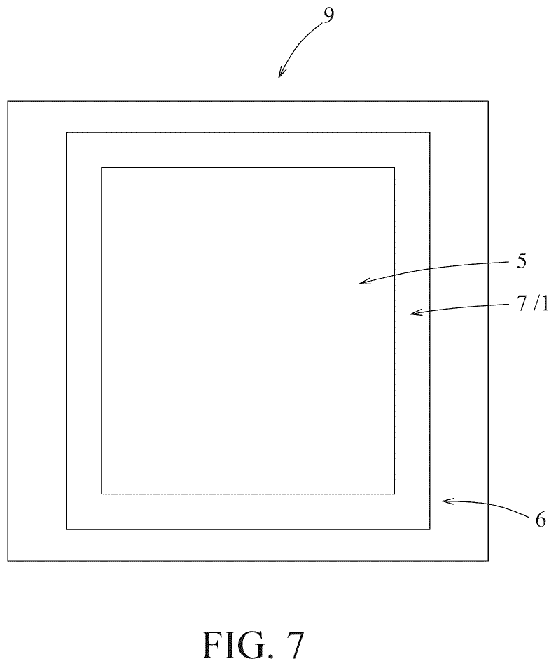

Referring to FIG. 7, the present disclosure also provides a field-effect transistor (FET) which includes a channel region 5, a gate dielectric layer 7 including the aforesaid superlattice structure 1 formed over the channel region 5, and a metal gate 6 formed over the gate dielectric layer 7.

In certain embodiments, the FET is a gate-all-around field-effect transistor (GAAFET) 9. As shown in FIG. 7, with regard to a partially schematic view of the GAAFET 9, the superlattice structure 1 serving as the gate dielectric layer 7 surrounds all side surfaces of the channel region 5, and the metal gate 6 surrounds all side surfaces of the superlattice structure 1. An example of a material of the channel region 5 may include, but is not limited to, silicon (Si). An example of a material of the metal gate 6 may include, but is not limited to, titanium nitride (TiN).

According to the present disclosure, the GAAFET 9 may be prepared using techniques well-known to those skilled in the art.

The present disclosure also provides a logic integrated circuit (logic IC) which includes the aforesaid FET. To be specific, the FET includes the gate dielectric layer 7 which includes the superlattice structure 1.

According to the present disclosure, by virtue of controlling the thickness of the superlattice structure 1 to range from 2.0 nm to 5.5 nm, controlling the thickness ratio of the hafnium dioxide layers 11 to the zirconium dioxide layers 12 to be 1:1, and conducting the RTA process at a temperature ranging from 450° C. to 800° C., the dielectric element including the superlattice structure 1 can exhibit a relatively high dielectric constant (K) and a relatively low equivalent oxide thickness (EOT), and hence can be utilized in the MIM capacitor, the FET, and the logic IC.

The disclosure will be further described by way of the following examples. However, it should be understood that the following examples are solely intended for the purpose of illustration and should not be construed as limiting the disclosure in practice.

### EXAMPLES

### Preparation of Metal-Insulator-Metal (MIM) Capacitor

### Example 1 (EX1)

A method for preparing a MIM capacitor 8 of EX1 includes the following steps in sequence: providing a silicon substrate 3, followed by subjecting the silicon substrate 3 to a Radio Corporation of America (RCA) standard cleaning process; forming a first titanium nitride layer (serving as a lower electrode layer 2), which had a thickness of 80 nm, on a surface of the silicon substrate 3 by a physical vapor deposition (PVD) process; forming alternately stacked hafnium dioxide layers 11 and zirconium dioxide layers 12 (abbreviated as a multi-stack oxide layer structure) on a surface of the lower electrode layer 2 opposite to the silicon substrate 3 by an atomic layer deposition (ALD) process; forming a second titanium nitride layer on a surface of the multi-stack oxide layer structure opposite to the lower electrode layer 2 by the PVD process, followed by subjecting the second titanium nitride layer to an electron beam lithography (EBL) process and then to a reactive ion etching (RIE) process so as to obtain a patterned upper electrode layer 4 which had a maximum thickness of 80 nm; and subjecting the resultant multi-layer laminate that contains the silicon substrate 3, the lower electrode layer 2, the multi-stack oxide layer structure, and the patterned upper electrode layer 4 stacked in such order to a rapid thermal annealing (RTA) process under a nitrogen atmosphere at a temperature of 450° C. for 30 seconds to allow the multi-stack oxide layer structure to undergo recrystallization so as to form a dielectric element having a superlattice structure 1, thereby obtaining the MIM capacitor 8 of EX1 which had an area of 10000 μm². In particular, the superlattice structure 1 had an ideal thickness of 5 nm, and included 5 layers of hafnium dioxide layers 11 and 5 layers of zirconium dioxide layers 12 that were alternately stacked, in which each of the hafnium dioxide layers 11 and the zirconium dioxide layers 12 had an ideal thickness of 0.5 nm.

### Examples 2 to 10 (EX2 to EX10)

The procedures and materials for preparing the MIM capacitors of EX2 to EX10 were similar to those of EX1, except that the total numbers of the hafnium dioxide layers 11 and the zirconium dioxide layers 12, the ideal thicknesses of each of the hafnium dioxide layers 11 and each of the zirconium dioxide layers 12, and the temperature for performing the RTA process were varied as shown in Tables 1 and 2 below.

The operation conditions and materials for preparing the MIM capacitors of EX1 to EX10 are summarized in Tables 1 and 2 below.

TABLE 1

| | EX1 | EX2 | EX3 | EX4 | EX5 |
|---|---|---|---|---|---|
| Temperature of RTA | 450 | 550 | 650 | 750 | 450 |
| process (° C.) | | | | | |
| Time period of RTA | 30 | 30 | 30 | 30 | 30 |
| process (s) | | | | | |
| Ideal thickness of | 0.5 | 0.5 | 0.5 | 0.5 | 0.8 |
| each of hafnium | | | | | |
| dioxide layers (nm) | | | | | |
| Total number of | 5 | 5 | 5 | 5 | 3 |
| hafnium dioxide | | | | | |
| layers (layer) | | | | | |
| Ideal thickness of | 0.5 | 0.5 | 0.5 | 0.5 | 0.8 |
| each of zirconium | | | | | |
| dioxide layers (nm) | | | | | |
| Total number of | 5 | 5 | 5 | 5 | 3 |
| zirconium dioxide | | | | | |
| layers (layer) | | | | | |
| Ideal thickness | 5 | 5 | 5 | 5 | 5 |
| of superlattice | | | | | |
| structure (nm) | | | | | |
| Actual thickness | 4.73 | 4.73 | 4.73 | 4.73 | 4.82 |
| of superlattice | | | | | |
| structure (nm) | | | | | |

TABLE 2

| | EX6 | EX7 | EX8 | EX9 | EX10 |
|---|---|---|---|---|---|
| Temperature of RTA | 550 | 650 | 450 | 550 | 650 |
| process (° C.) | | | | | |
| Time period of RTA | 30 | 30 | 30 | 30 | 30 |
| process (s) | | | | | |
| Ideal thickness of | 0.8 | 0.8 | 1.3 | 1.3 | 1.3 |
| each of hafnium | | | | | |
| dioxide layers (nm) | | | | | |
| Total number of | 3 | 3 | 2 | 2 | 2 |
| hafnium dioxide | | | | | |
| layers (layer) | | | | | |
| Ideal thickness of | 0.8 | 0.8 | 1.3 | 1.3 | 1.3 |
| each of zirconium | | | | | |
| dioxide layers (nm) | | | | | |
| Total number of | 3 | 3 | 2 | 2 | 2 |
| zirconium dioxide | | | | | |
| layers (layer) | | | | | |
| Ideal thickness | 5 | 5 | 5 | 5 | 5 |
| of superlattice | | | | | |
| structure (nm) | | | | | |
| Actual thickness | 4.82 | 4.82 | 4.76 | 4.76 | 4.76 |
| of superlattice | | | | | |
| structure (nm) | | | | | |

Note: The term “ideal thickness” refers to an intended thickness set when preparing the hafnium dioxide layers 11 and the zirconium dioxide layers 12. However, due to potential errors caused by the equipment conditions during preparation, the idea thickness of the hafnium dioxide layers 11, the zirconium dioxide layers 12, or the superlattice structure 1 may differ from the actual thickness thereof.

### Preparation of Gate-all-Around Field-Effect Transistor (GAAFET)

### Example 1′ (EX1′)

Briefly, a method for preparing a GAAFET 9 of EX1′ includes the following steps in sequence: providing a silicon on insulator (SOI) wafer, follows by subjecting the SOI wafer to a buffered oxide etching (BOE) process and then to a RCA standard cleaning process for cleaning the SOI wafer; subjecting the thus cleaned SOI wafer to a low pressure chemical vapor deposition (LPCVD) process so as to form epitaxial triple-cycle stacked silicon-germanium/silicon (SiGe/Si) layers on the thus cleaned SOI wafer, followed by subjecting the epitaxial triple-cycle stacked SiGe/Si layers to a EBL process and then to a RIE process, thereby defining and forming an active region; subjecting the stacked SOI wafer and epitaxial triple-cycle stacked SiGe/Si layers to impregnation in a sulfuric acid (H₂SO₄)/hydrogen peroxide (H₂O₂) mixture (SPM, H₂SO₄:H₂O₂=4:1) at a temperature of 120° C. for 10 minutes, followed by impregnation in a dilute hydrofluoric acid solution (DHF, hydrofluoric acid:DI water=1:50) at room temperature for 10 seconds, and then impregnation in a buffer oxide etching (BOE, ammonium fluoride:hydrofluoric acid=7:1) for cleaning the stacked SOI wafer and epitaxial triple-cycle stacked SiGe/Si layers; subjecting the epitaxial triple-cycle stacked SiGe/Si layers to a wet etching, so as to remove the SiGe layer therein such that the Si layer served as a channel region 5; forming alternately stacked hafnium dioxide layers 11 and zirconium dioxide layers 12 (abbreviated as a multi-stack oxide layer structure) around all side surfaces of the channel region 5 by an ALD process at a temperature of 250° C.; forming a titanium nitride layer (serving as a metal gate 6) around all side surfaces of the multi-stack oxide layer structure by an ALD process and a PVD process in sequence, followed by subjecting the metal gate 6 to a EBL process and then to a RIE process, so as to pattern and etch the metal gate 6 to expose portions of the active region including the channel region 5 and the multi-stack oxide layer structure; conducting an ion implantation process with a doping concentration of 1×10¹⁵/cm³ so as to form a source and a drain; and subjecting the resultant wraparound multi-layer structure that includes the channel region 5, the multi-stack oxide layer structure, the metal gate 6, the source, and the drain to a RTA process under a nitrogen atmosphere at a temperature of 450° C. for 30 seconds to active previously doped ions and to allow the multi-stack oxide layer structure to undergo recrystallization so as to form a gate dielectric layer 7 including a superlattice structure 1, thereby obtaining the GAAFET 9 of EX1′ which had a channel width (W_{CH}) of 35 nm and a gate length (L_{G}) of 80 nm. In particular, the superlattice structure 1 had an ideal thickness of 5 nm and included 5 layers of hafnium dioxide layers 11 and 5 layers of zirconium dioxide layers 12 that were alternately stacked, in which each of the hafnium dioxide layers 11 and the zirconium dioxide layers 12 had an ideal thickness of 0.5 nm.

### Comparative Example 1′ (CE1′)

The procedures and materials for preparing the GAAFET of CE′1 were similar to those of EX1′, except that a hafnium dioxide layer served as a gate dielectric layer.

### Property Evaluation

### A. Determination of Actual Thickness

The dielectric element in a respective one of the MIM capacitors of EX1 to EX10 and the gate dielectric layer in a respective one of the GAAFETs of EX1′ and CE1′ were subjected to determination of actual thickness using a transmission electron microscope (Manufacturer: JEOL Ltd., Model no.: JEM3000F). The results of the dielectric element in a respective one of the MIM capacitors of EX1 to EX10 are shown in Table 1 and Table 2 above. With regard to the GAAFET of EX1′, the gate dielectric layer 7 in the GAAFET of EX1′ had an actual thickness of 5.13 nm, in which each of the hafnium dioxide layers 11 and the zirconium dioxide layers 12 had an actual thickness of 0.513 nm. With regard to the GAAFET of CE1′, the gate dielectric layer in the GAAFET of CE1′ had an actual thickness of 5.0 nm.

### B. Calculation of Dielectric Constant (K)

The dielectric constant (K) of the dielectric element in the respective one of the MIM capacitors of EX1 to EX10 and the gate dielectric layer in the respective one of the GAAFETs of EX1′ and CE1′ was calculated using the following

$$Equation ( 1 )$$

$$κ = ( C \times d ) / ( ε 0 \times A ) \qquad ( 1 )$$

where
κ=dielectric constant (K)
C=capacitance value of dielectric element or gate dielectric layer
d=actual thickness of dielectric element or gate dielectric layer
ε0=permittivity of free space (i.e., 8.854×10⁻¹⁴ F/cm)
A=area of dielectric element or gate dielectric layer

The results are shown in Table 3 below.

### C. Calculation of Equivalent Oxide Thickness (EOT)

The EOT of the dielectric element in the respective one of the MIM capacitors of EX1 to EX10 and the gate dielectric layer in the respective one of the GAAFETs of EX1′ and CE1′ was calculated using the following Equation (2):

$$E O T = {t}_{1} \times ( {κ}_{{SiO}_{2}} / {κ}_{1} ) \qquad ( 2 )$$

where
EOT=equivalent oxide thickness
t₁=actual thickness of dielectric element or gate dielectric layer
κ_{SiO}_{₂}=dielectric constant (κ) of silicon dioxide (i.e., 3.9)
κ₁=dielectric constant (κ) of dielectric element or gate dielectric layer

The results are shown in Table 3 below.

### D. Current Density-Voltage (J-V) Analysis

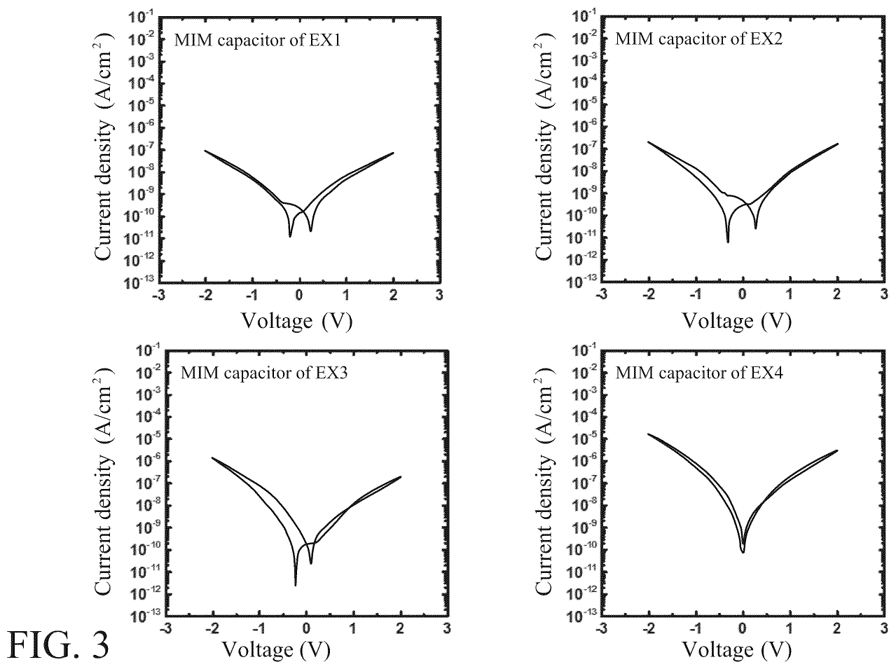

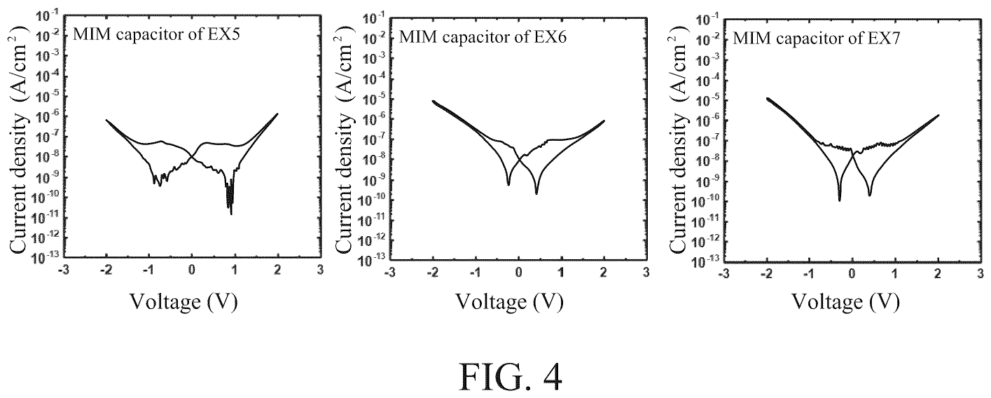

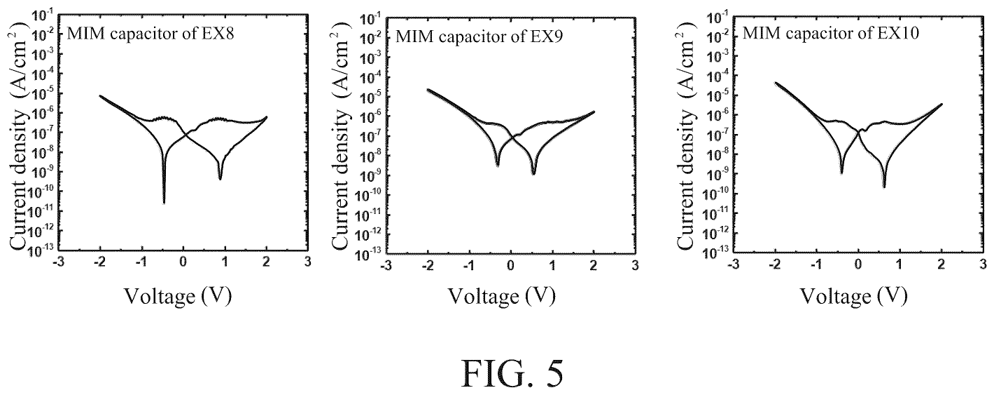

The respective one of the MIM capacitors of EX1 to EX10 was subjected to current density-voltage (J-V) analysis using a semiconductor device parameter analyzer (Manufacturer: Keysight, Model no.: B1500A), so as to obtain current density-voltage (J-V) curves as shown in FIGS. 3 to 5.

### E. Polarization-Voltage (P-V) Analysis

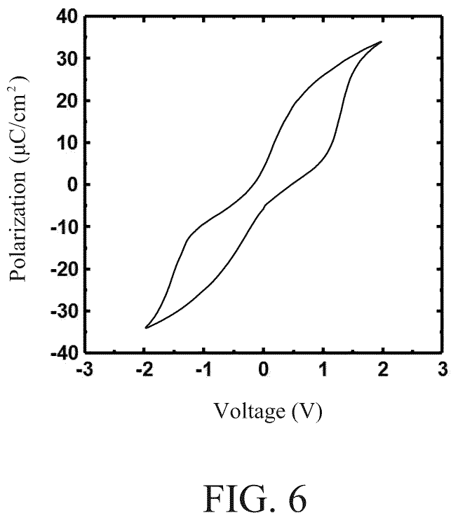

The MIM capacitor of EX1 was subjected to polarization-voltage (P-V) analysis using the semiconductor device parameter analyzer, so as to obtain a polarization-voltage (P-V) hysteresis loop as shown in FIG. 6.

F. Drain Current-Gate Voltage (I_{D}-V_{G}) Analysis

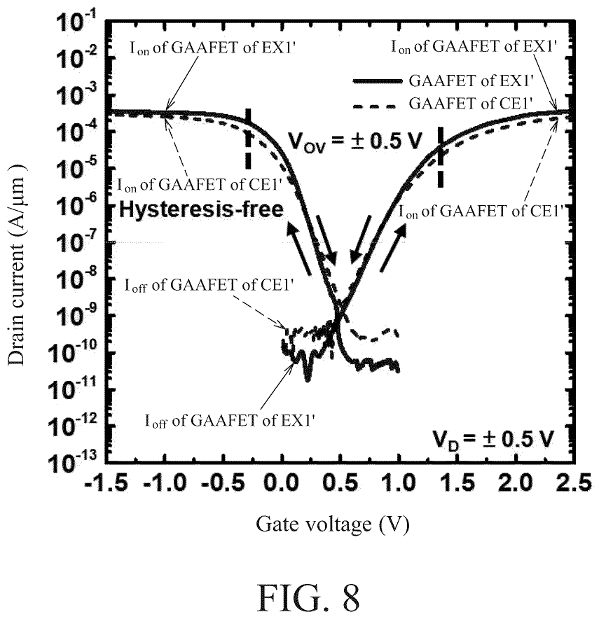

The respective one of the GAAFETs of EX1′ and CE1′ was subjected to drain current-gate voltage (I_{D}-V_{G}) analysis using the semiconductor device parameter analyzer, so as to obtain drain current-gate voltage (I_{D}-V_{G}) curves as shown in FIG. 8.

G. Drain Current-Drain Voltage (I_{D}-V_{D}) Analysis

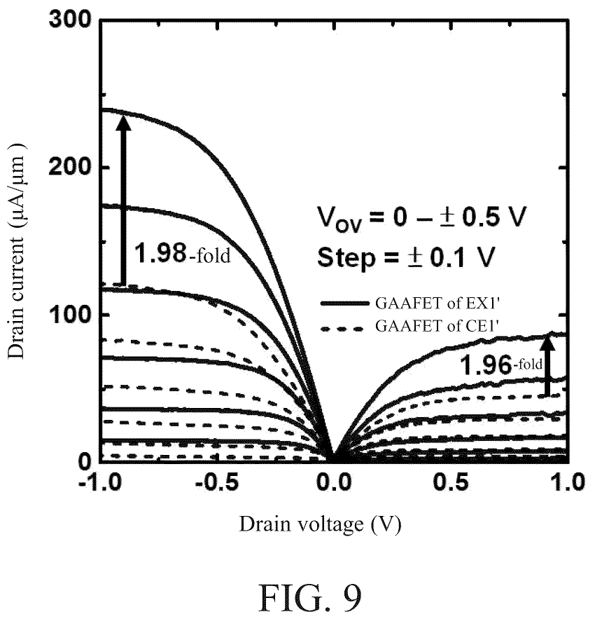

The respective one of the GAAFETs of EX1′ and CE1′ was subjected to drain current-drain voltage (I_{D}-V_{D}) analysis using the semiconductor device parameter analyzer, so as to obtain drain current-drain voltage (I_{D}-V_{D}) curves as shown in FIG. 9.

### Results

TABLE 3

| | EX1 | EX2 | EX3 | EX4 | EX5 | EX6 |
|---|---|---|---|---|---|---|
| Dielectric constant (κ) | 52.25 | 51.88 | 49.95 | 43.66 | 41.16 | 39.78 |
| EOT (Å) | 3.5 | 3.6 | 3.7 | 4.2 | 4.6 | 4.7 |
| | EX7 | EX8 | EX9 | EX10 | EX1′ | CE1′ |
| Dielectric constant (κ) | 36.72 | 37.2 | 36.6 | 32.96 | 52.25 | 25 |
| EOT (Å) | 5.1 | 5 | 5.1 | 5.6 | 3.8 | 7.8 |

Referring to Table 3, the dielectric constant (κ) of the dielectric element in the respective one of the MIM capacitors of EX1 to EX10 ranged from 32.96 to 52.25, indicating that the dielectric constant (κ) of the dielectric element including the superlattice structure 1 of the present disclosure was approximately as high as 30 to 53. Referring to FIGS. 3 to 5, a leakage current generated by the respective one of the MIM capacitors of EX1 to EX10 was all below 10⁻³ A/cm², demonstrating that the dielectric element including the superlattice structure 1 of the present disclosure, which had the dielectric constant (κ) approximately ranging from 30 to 53, could effectively control the leakage current generated by MIM capacitors.

Referring to FIG. 6, the P-V hysteresis loop of the MIM capacitor of EX1 had a gourd shape, indicating that the interface between different materials (i.e., the hafnium dioxide layers 11 having an orthorhombic phase and the zirconium dioxide layers 12 having a tetragonal phase) in the dielectric element of the MIM capacitor of EX1 formed a morphotropic phase boundary (MPB), thereby confirming that the dielectric element including the superlattice structure 1 of the present disclosure in the MIM capacitor of EX1 had a relatively high dielectric constant (κ).

Referring to Table 3, the gate dielectric layer 7 in the GAAFET of EX1′ had the dielectric constant (κ) of 52.25 and the EOT of 3.8 Å, while the gate dielectric layer in the GAAFET of CE1′ had the dielectric constant (κ) of 25 and the EOT of 7.8 Å. These results demonstrate that the dielectric element including the superlattice structure 1 of the present disclosure, which serves as the gate dielectric layer 7 in a FET, can exhibit a relatively high dielectric constant (κ) and a relatively low EOT.

Referring to FIG. 8, a leakage current generated by the GAAFET of EX1′ was below 10⁻³ A/cm², indicating that the dielectric element, which included the superlattice structure 1 of the present disclosure and which had the relatively high dielectric constant (κ, i.e., 52.25), could serve as an gate dielectric layer 7 in a FET, which could reduce an occurrence of leakage currents therein, thereby enhancing transmission efficiency of the FET and enabling a logic integrated circuit (logic IC) containing the aforementioned FET to have a relatively high computational performance and a relatively low power consumption.

Referring to FIG. 8 again, the GAAFET of EX1′ had an on-state current/off-state current (Iₒₙ/I_{off}) ratio of 1.14×10⁷ and a subthreshold swing (SSₘᵢₙ) of 69 mV/dec, while the GAAFET of CE1′ had an Iₒₙ/I_{off} ratio of 4.02×10⁶ and an SSₘᵢₙ of 112 mV/dec. These results demonstrate that the dielectric element including the superlattice structure 1 of the present disclosure, which serves as the gate dielectric layer 7 in a FET, can effectively increase a drain current, thereby enhancing a switching speed of the FET containing the dielectric element and enabling a logic IC containing the aforementioned FET to have a relatively high computational performance.

Referring to FIG. 9, a drive current measured in the GAAFET of EX1′ at an overdrive voltage (Vₒᵥ) of +0.5 V or −0.5 V was almost twice as high as a drive current measured in the GAAFET of CE1′ at the same overdrive voltage (Vₒᵥ) of +0.5 V or −0.5 V, indicating that the dielectric element including the superlattice structure 1 of the present disclosure, which serves as the gate dielectric layer 7 in the FET, could effectively increase the drain current, thereby enhancing the switching speed of the FET containing the dielectric element and enabling the logic IC containing the aforementioned FET to have the relatively high computational performance.

Summarizing the above test results, it is clear that by virtue of controlling the thickness of the superlattice structure 1 to range from 2.0 nm to 5.5 nm, controlling the thickness ratio of the hafnium dioxide layers 11 to the zirconium dioxide layers 12 to be 1:1, and conducting the RTA process at a temperature ranging from 450° C. to 800° C., the dielectric element including the superlattice structure 1 of the present disclosure can exhibit a relatively high dielectric constant (κ) and a relatively low equivalent oxide thickness (EOT), and hence can be utilized in the MIM capacitor, the FET, and the logic IC, thereby effectively controlling a leakage current generated by MIM capacitors, enhancing transmission efficiency and a switching speed of the FET, and enabling the logic IC to have a relatively high computational performance and a relatively low power consumption.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, the one or more features may be singled out and practiced alone without the another one or more features or specific details. It should be further noted that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A dielectric element, comprising a superlattice structure which includes hafnium dioxide (HfO₂) layers and zirconium dioxide (ZrO₂) layers that are alternately stacked,
wherein the superlattice structure has a total thickness ranging from 2.0 nm to 5.5 nm and a dielectric constant (κ) ranging from 30 to 53, and a thickness ratio of the hafnium dioxide layers to the zirconium dioxide layers is 1:1.

2. The dielectric element as claimed in claim 1, wherein the total number of the hafnium dioxide layers is equal to the total number of the zirconium dioxide layers.

3. The dielectric element as claimed in claim 1, wherein each of the hafnium dioxide layers has a thickness ranging from 0.3 nm to 1.5 nm, and each of the zirconium dioxide layers has a thickness ranging from 0.3 nm to 1.5 nm.

4. The dielectric element as claimed in claim 3, which is prepared by subjecting the hafnium dioxide layers and the zirconium dioxide layers to a rapid thermal annealing (RTA) process at a temperature ranging from 450° C. to 800° C.

5. The dielectric element as claimed in claim 4, which is prepared by subjecting the hafnium dioxide layers each having a thickness of 0.5 nm and the zirconium dioxide layers each having a thickness of 0.5 nm to the RTA process at a temperature ranging from 450° C. to 750° C.

6. The dielectric element as claimed in claim 4, which is prepared by subjecting the hafnium dioxide layers each having a thickness of 0.8 nm and the zirconium dioxide layers each having a thickness of 0.8 nm to the RTA process at a temperature ranging from 450° C. to 650° C.

7. The dielectric element as claimed in claim 4, which is prepared by subjecting the hafnium dioxide layers each having a thickness of 1.3 nm and the zirconium dioxide layers each having a thickness of 1.3 nm to the RTA process at a temperature ranging from 450° C. to 650° C.

8. A field-effect transistor (FET), comprising:
a channel region;
the dielectric element as claimed in claim 1 serving as a gate dielectric layer and formed over the channel region; and
a metal gate formed over the gate dielectric layer.

9. The FET as claimed in claim 8, which is a gate-all-around field-effect transistor (GAAFET).

10. A logic integrated circuit (logic IC), comprising the FET as claimed in claim 8.

11. A metal-insulator-metal (MIM) capacitor, comprising the dielectric element as claimed in claim 1.
